(19) United States
(12) Patent Application Publication
(10) Pub. No.: US 2025/0356091 A1
(43) Pub. Date: Nov. 20, 2025

(54) System and Method for Checking Mismatches in Current Mirror Circuit

(71) Applicant: Taiwan Semiconductor Manufacturing Company, Ltd., Hsinchu (TW)

(72) Inventors: Mao-Hsuan Chou, Hsinchu (TW); Cheng-Yu Tsai, Hsinchu (TW); Cheng-Hsiang Hsieh, Hsinchu (TW); Ruey-Bin Sheen, Hsinchu (TW); Chih-Hsien Chang, Hsinchu (TW); Liang-Sheng Tsai, Hsinchu (TW)

(21) Appl. No.: 18/919,579

(22) Filed: Oct. 18, 2024

Related U.S. Application Data
(60) Provisional application No. 63/649,709, filed on May 20, 2024.

(51) Int. Cl. G06F 30/3323; G01R 19/165; G01R 31/26

(52) U.S. Cl. CPC G06F 30/3323; G01R 19/16533; G01R 31/2601

(57) ABSTRACT

A method includes calculating a mismatch value between an input current associated with a master transistor of a current mirror circuit and a second current associated with a second transistor of the current mirror circuit, comparing the mismatch value to a predetermined mismatch threshold, and generating a comparison result that specifies whether the mismatch value exceeds the predetermined mismatch threshold. The parameter associated with the first transistor or the second transistor is modified when the mismatch value exceeds the predetermined mismatch threshold.

### CROSS-REFERENCE TO RELATED APPLICATION

The present application claims priority to U.S. Provisional Application No. 63/649,709, filed May 20, 2024, the contents of which are incorporated by reference herein in its entirety.

### BACKGROUND

Semiconductor devices (e.g., integrated circuits and semiconductor chips or dies) may incorporate one or more current mirror circuits, each generating an output current that is a replicated or a scaled version (e.g., a multiple or a fraction) of an input current. A current mirror circuit can serve as a current source for other circuits of the semiconductor device, such as a bandgap reference circuit, and may provide a relatively stable current that facilitates consistent operation, e.g., producing a stable reference voltage, within the semiconductor device.

### BRIEF DESCRIPTION OF THE DRAWINGS

Aspects of the present disclosure are best understood from the following detailed description when read with the accompanying figures:

FIG. 1 is a schematic block diagram illustrating an exemplary system in accordance with various embodiments of the present disclosure;

FIG. 2 is a schematic circuit diagram illustrating an exemplary current mirror circuit of a semiconductor chip in accordance with various embodiments of the present disclosure;

FIG. 3 is a schematic block diagram illustrating an exemplary system in accordance with various embodiments of the present disclosure;

FIG. 4 is a schematic diagram illustrating an exemplary GUI (Graphical User Interface) of a system in accordance with various embodiments of the present disclosure;

FIG. 5 is a plot illustrating an exemplary relationship between parameters of a transistor of a current mirror circuit in accordance with various embodiments of the present disclosure.;

FIG. 6 is a plot illustrating another exemplary relationship between parameters of a transistor of a current mirror circuit in accordance with various embodiments of the present disclosure;

FIG. 7 is a plot illustrating another exemplary relationship between parameters of a transistor of a current mirror circuit in accordance with various embodiments of the present disclosure;

FIG. 8 is a plot illustrating an exemplary sigma level in accordance with various embodiments of the present disclosure;

FIG. 9 is a schematic circuit diagram illustrating an exemplary semiconductor chip in accordance with various embodiments of the present disclosure;

FIG. 10 is a flowchart illustrating an exemplary method of obtaining a mismatch value between input and output currents of a current mirror circuit in accordance with various embodiments of the present disclosure; and

FIG. 11 is a schematic block diagram illustrating an exemplary computing device architecture in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As noted above, semiconductor chips may incorporate one or more current mirror circuits, each generating an output current that is a replicated or scaled version (e.g., a multiple or a fraction) of an input current. For example, an input current, e.g., from a current source circuit, is established through a master transistor of a current mirror circuit. A slave transistor of the current mirror circuit mirrors the input current. When the slave transistor has substantially identical characteristics, such as size (e.g., W/L ratio), to those of the master transistor, it will conduct an output current substantially equal to the input current.

A mismatch between input and output currents in a current mirror circuit could cause malfunctions in semiconductor chips, resulting in low manufacturing yields. Certain systems and methods as described herein analyze the mirror current circuit for mismatches before manufacturing the semiconductor chip. For example, if a detected mismatch value is greater than the predetermined mismatch threshold, i.e., a mismatch occurs between the input and output currents, a circuit design of the current mirror circuit may be modified to reduce the mismatch value. Conversely, if the mismatch value is within the predetermined mismatch threshold, i.e., the output current substantially matches the input current, the checking and/or modification processes proceeds to be performed on the other current mirror circuits of the semiconductor chip. This can help ensure a high manufacturing yield for the semiconductor chip.

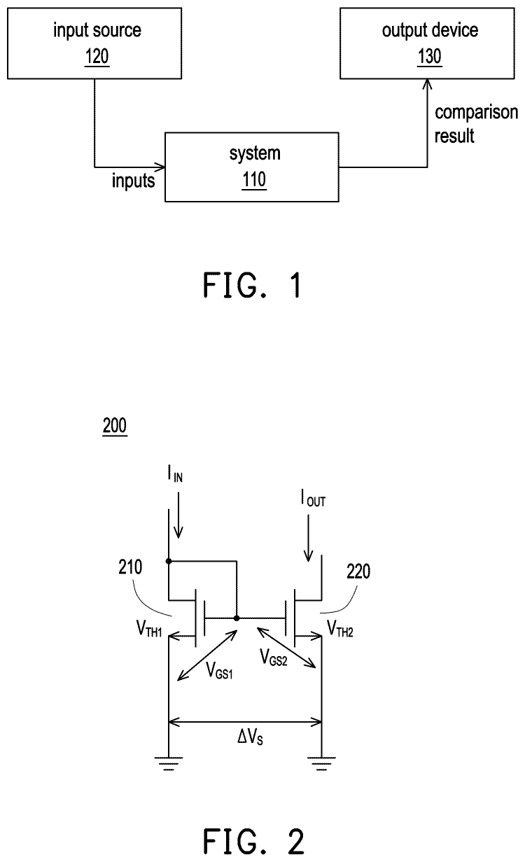

FIG. 1 is a schematic block diagram illustrating an exemplary system 110 connected between an input source 120 and an output device 130 in accordance with various embodiments of the present disclosure. As will be described hereinafter, the example system 110 checks whether a mismatch occurs between input and output currents of a current mirror circuit of a semiconductor chip. For example, as illustrated in FIG. 1, the system 110 is connected between an input source 120 and an output device 130 and collects a plurality of inputs from the input source 120. These inputs can be used to obtain a mismatch value between input and output currents of a current mirror circuit of a semiconductor chip. The mismatch value is then compared to a predetermined mismatch threshold to determine if the mismatch value is within an acceptable limit. The system indicates the comparison result using the output device 130. For example, in some embodiments, the output device 130 includes a computer monitor. In such some embodiments, if the mismatch value exceeds the predetermined mismatch threshold, the output device 130 displays a “FAIL.” Otherwise, a “PASS” is displayed by the output device 130. In other embodiments, the output device 130 further includes a computer speaker, a computer printer, a light indicator, a buzzer, and the like. The output current generated by the current mirror circuit can be used to bias other circuits of the semiconductor chip, e.g., a bandgap reference circuit to produce a relatively stable reference voltage.

From the above description, checking for mismatches in a current mirror circuit ensures reliability and performance of a semiconductor chip, facilitating early detection of potential issues, and improving overall yield. For instance, if the current mirror circuit is found to have a mismatch value exceeding the predetermined mismatch threshold, it can be redesigned to correct the discrepancy. This iterative process enhances accuracy of the current mirror circuit, thereby increasing the yield of the semiconductor chip. Additionally, this reduces the likelihood of field failures, and optimize the manufacturing process by identifying and addressing design flaws early on. This proactive approach ultimately leads to more robust and dependable semiconductor devices, benefiting both manufacturers and end-users. Following adjustments of the design, one or more physical semiconductor chips are fabricated based on the adjusted design.

Example supporting circuitry for the current mirror circuit 200 is depicted in FIG. 2. It is understood that this circuitry is provided by way of example, not by limitation, and other suitable circuitry are within the scope of the present disclosure. FIG. 2 is a schematic circuit diagram illustrating an exemplary current mirror circuit 200 in accordance with various embodiments of the present disclosure. As illustrated in FIG. 2, the current mirror circuit 200 includes a master transistor 210 and a slave transistor 220, at least one of which is in the form of a metal-oxide-semiconductor field-effect transistor (MOSFET), e.g., an n- or p-type MOSFET. The master transistor 210 has a first source/drain terminal and a gate terminal connected to each other and to the gate terminal of the slave transistor. The second source/drain terminal of the master transistor and the second source/drain terminal of the slave transistor are connected to each other and to a reference voltage or an electrical ground.

In an exemplary operation, an input current (I_{IN}) is supplied, e.g., by a constant current source, to the first source/drain terminal of the master transistor 210. Because the gate terminal of the master transistor 210 is connected to the first source/drain terminal of the master transistor 210, the master transistor 210 operates in saturation mode, ensuring a stable flow of the input current (I_{IN}) therethrough. The voltage at the gate terminal of the master transistor 210 is shared with the gate terminal of the slave transistor 220. This ensures that both transistors 210, 220 have a substantially the same gate-source voltage (V_{GS1}, V_{GS2}). Due to this shared gate-source voltage (V_{GS1}, V_{GS2}), the slave transistor 220 also operates in saturation mode and mirrors the input current (I_{IN}) from the master transistor 210. In some embodiments, the output current (I_{OUT}) of the slave transistor 220 may be substantially equal to the input current (I_{IN}). In other embodiments, the output current (I_{OUT}) may be scaled to be a multiple/fraction of the input current (I_{IN}), e.g., by adjusting the size, e.g., W/L ratio, of the slave transistor 220 relative to the master transistor 210. The input current (I_{IN}) can be calculated using Equation (1):

$${I}_{IN} = {μ}_{n} {C}_{OX} \frac{W}{L} {( {V}_{G S} - {V}_{T H} )}^{2} \qquad ( 1 )$$

where μₙC_{OX} is the predetermined constant, L is the gate length of the master transistor 210, W is the channel width of the master transistor 210, V_{GS} is the gate-source voltage of the master transistor 210, and V_{TH} is the threshold voltage of the master transistor 210.

In addition, the voltage difference (ΔV_{S}, ΔV_{TH}) between the source/threshold voltage of the master transistor 210 and the source/threshold voltage of the slave transistor 220 is defined by Equations (2) and (3):

$$Δ {V}_{S} = {V}_{GS 2} - {V}_{GS 1} \qquad ( 2 )$$

where V_{GS1} is the gate-source voltage of the master transistor 210 and V_{GS2} is the gate-source voltage of the slave transistor 220.

$$Δ {V}_{T H} = {V}_{TH 2} - {V}_{TH 1} \qquad ( 3 )$$

where V_{TH1} is the threshold voltage of the master transistor 210 and V_{TH2} is the threshold voltage of the slave transistor 220.

Moreover, the mismatch value (M_{V}) between the input and output currents (I_{IN}, I_{OUT}) of the current mirror circuit 200 is given by Equation (4):

$${M}_{V} = \vert \frac{{I}_{OUT}}{{I}_{IN}} - 1 \vert \qquad ( 4 )$$

As will be described further below, these Equations (1)-(4) facilitate the verification of a current mismatch and aid in the analysis and optimization of the design and performance of the current mirror circuit 200, ensuring it meets the desired specifications and operational criteria.

In certain embodiments, the output current (I_{OUT}) can be a multiple or a fraction of the input current (I_{IN}). This is achieved when the slave transistor 220 has a different size than the master transistor 210. For example, if the slave transistor 220 has a W/L ratio that is n times larger than the W/L ratio of the master transistor 210, the output current (I_{OUT}) will be substantially n times the input current. Conversely, if the slave transistor 220 has a W/L ratio that is 1/n times smaller than the W/L ratio of the master transistor 210, the output current (I_{OUT}) will be substantially 1/n times the input current (I_{IN}).

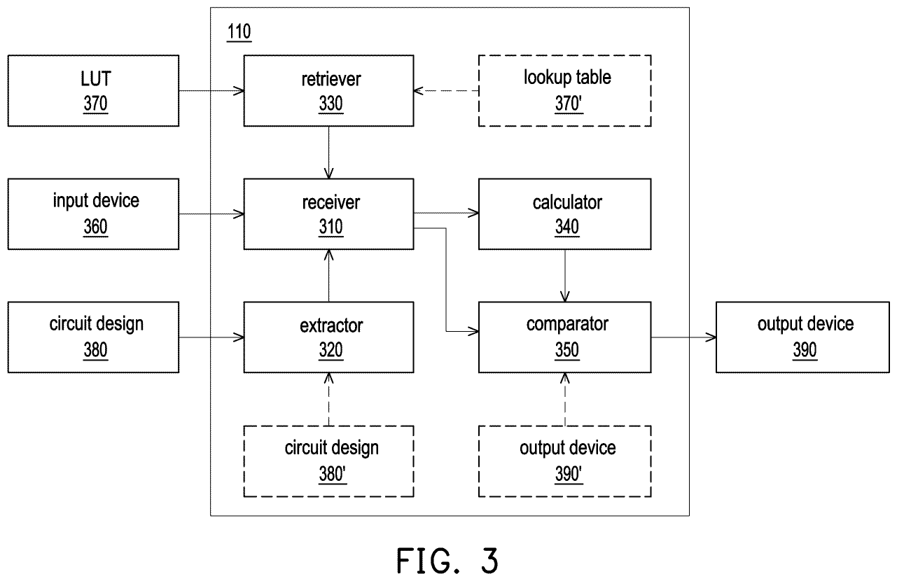

FIG. 3 is a schematic block diagram illustrating another exemplary system 110 in accordance with various embodiments of the present disclosure. As illustrated in FIG. 3, the example system 110 includes a receiver 310, an extractor 320, a retriever 330, a calculator 340, and a comparator 350. The receiver 310 collects one or more inputs from one or more input sources, e.g., an input device 360, a look-up table (LUT) 370, and a circuit design 380. For example, with further reference to FIG. 2, the input device 360 accepts one or more specifications that includes a predetermined mismatch threshold (Source_{MM}), the voltage difference (ΔV_{S}), and the input current (I_{IN}). The input device 360 then transmits these specifications to the receiver 310. In certain embodiments, the input device 360 is in the form of a computer keyboard, a computer mouse, a touchscreen, other suitable input devices, or combinations thereof.

The predetermined mismatch threshold (Source_{MM}), e.g., expressed as a percentage (such as 5%), represents the maximum mismatch value (M_{V1}) between the input and output currents (I_{IN}, I_{OUT}). That is, when the mismatch value (M_{V1}) exceeds the predetermined mismatch threshold (Source_{MM}), it indicates that the output current (I_{OUT}) significantly deviates from the input current (I_{IN}), implying that the current mirror circuit 200 is inaccurately replicating the input current (I_{IN}). On the other hand, when the mismatch value (M_{V1}) is within the predetermined mismatch threshold (Source_{MM}), the output current (I_{OUT}) closely duplicates the input current (I_{IN}), suggesting reliable performance and adherence to desired specifications by the current mirror circuit 200.

The extractor 320 extracts one or more parameters from a circuit design 380, which corresponds to the current mirror circuit 200, and transmits the parameters extracted thereby to the receiver 310. For example, these parameters include the channel width (W) and the gate length (L). In some embodiments, the circuit design 380 may be generated by a circuit design 380 engineer using an electronic design automation (EDA) tool or a circuit simulation software. In such some embodiments, the extractor 320 communicates with the circuit design tool/software, e.g., via a local or wide area network (LAN or WAN), to obtain the parameters.

The channel width (W) is given by Equation (5):

$$W = ( m ) ( {N}_{finger} ) ( w ) \qquad ( 5 )$$

where m is the number of master transistors 210 connected in parallel, N_{finger} is the number of fingers of the gate region of each master transistor 210, and w is the channel width of each gate region.

The gate length (L) is given by Equation (6):

$$L = ( {N}_{stack} ) ( {l}_{g} ) \qquad ( 6 )$$

where N_{stack} is the number of master transistors 210 connected in series and l_{g} is the gate length of each master transistor 210.

The retriever 330 retrieves one or more predetermined constants, e.g., the predetermined constant (μₙC_{OX}), from the LUT 370 and transmits the predetermined constant (μₙC_{OX}) retrieved thereby to the receiver 310. In summary, as shown in Table 1 below, the receiver 310 receives the specifications (e.g., the predetermined mismatch threshold Source_{MM}, the voltage difference ΔV_{S}, and the input current I_{IN}) from the input device 360, the parameters (e.g., the channel width W and the gate length L) from the extractor 320, and the predetermined constant (μₙC_{OX}) from the retriever 330.

TABLE 1

| Notation | Description | Input Source |
|---|---|---|
| Source_{MM} | predetermined mismatch threshold | input device |
| ΔVₛ | voltage difference | input device |
| I_{IN} | input current | input device |
| W | channel width, (m)(N_{fingers})(w) | circuit design |
| L | gale length, (N_{stack})(Ig) | circuit design |
| μₙC_{OX} | predetermined constant | LUT |

The receiver 310 transmits the specifications (ΔV_{S}, I_{IN}), the parameters (W, L), and the predetermined constant (μₙC_{OX}) received thereby from the input device 360, the extractor 320, and the retriever 330 to the calculator 340. The calculator 340 computes a mismatch value (M_{V1}) based on these metrics (ΔV_{S}, I_{IN}, W, L, μₙC_{OX}) using Equation (7):

$${M}_{V 1} = {( 1 + \frac{Δ {V}_{S}}{\sqrt{\frac{{I}_{IN}}{{μ}_{n} {c}_{OX} \frac{W}{L}}}} )}^{2} - 1 \qquad ( 7 )$$

Equation (7) can be derived from Equations (1), (2), and (4). For example, by rearranging Equation (1), it is obtained:

$${V}_{G S} - {V}_{T H} = \sqrt{\frac{{I}_{IN}}{{μ}_{n} {c}_{OX} \frac{W}{L}}} \qquad ( 8 )$$

Substituting Equation (1) into Equation (4) yields:

$${M}_{V 1} = \frac{{μ}_{n} {C}_{OX} \frac{W}{L} {( {V}_{GS 2} - {V}_{TH} )}^{2}}{{μ}_{n} {C}_{OX} \frac{W}{L} {( {V}_{GS 1} - {V}_{TH} )}^{2}} - 1 \qquad ( 9 )$$

By cancelling the predetermined constant (μₙC_{OX}), Equation (10) is obtained as follows:

$${M}_{V 1} = \frac{{( {V}_{GS 2} - {V}_{TH} )}^{2}}{{( {V}_{GS 1} - {V}_{TH} )}^{2}} - 1 \qquad ( 10 )$$

Substituting Equation (2) into Equation (10) results in:

$${M}_{V 1} = \frac{{( {V}_{GS 1} - {V}_{TH} + Δ {V}_{S} )}^{2}}{{( {V}_{GS 1} - {V}_{TH} )}^{2}} - 1 \qquad ( 11 )$$

Simplifying Equation (11) yields:

$${M}_{V 1} = {( 1 + \frac{Δ {V}_{S}}{{V}_{GS 1} - {V}_{TH}} )}^{2} - 1 \qquad ( 12 )$$

Finally, inserting Equation (8) into Equation (12) results in Equation (7).

The receiver 310 transmits the specification (Source_{MM}) received thereby from the input device 360 to the comparator 350. The calculator 340 transmits the mismatch value (M_{V1}) that it calculated to the comparator 350. The comparator 350 then compares the mismatch value (M_{V1}) to the predetermined mismatch threshold (Source_{MM}) and generates a comparison result. The output device 390 indicates whether there is a mismatch between input and output currents (I_{N}, I_{OUT}) based on the comparison result. For example, in some embodiments, the output device 390 is a computer monitor. In such some embodiments, if the mismatch value (M_{V1}) is greater than the predetermined mismatch threshold (Source_{MM}), the output device 390 displays “FAIL.” Otherwise, a “Pass” is displayed by the output device 390. In other embodiments, the output device 390 may be a computer speaker, a computer printer, other output devices capable of indicating the comparison result, or combinations thereof.

In an alternative embodiment, the system 100 includes at least one of the LUT 370, the circuit design 380, and the output device 390, as indicated by the dashed box. This configuration allows for a flexible and modular design, enabling the system 100 to be tailored to specific needs and applications. For instance, the inclusion of the LUT 370 provides a means to quickly retrieve the predetermined constants (μₙC_{OX}). Likewise, the parameters of the circuit design 380 can also be reliably extracted by the extracted by the extractor 320. This modular approach not only enhances the system's 110 versatility but also improves its ability to integrate into various existing setups and workflows.

The preceding sections describe the process of determining a mismatch value (M_{V1}) between the input and output currents (I_{N}, I_{OUT}) of the mirror current circuit 200, which is caused by the voltage difference (ΔV_{S}) between the source voltage (V_{S1}) of the master transistor 210 and the source voltage (V_{S2}) of the slave transistor 220. The following sections involve evaluating how the voltage difference (ΔV_{TH}) between the threshold voltage (V_{TH1}) of the master transistor 210 and the threshold voltage (V_{TH2}) of the slave transistor 220 contributes to a mismatch value (M_{V2}).

Referring back to FIG. 3, the receiver 310 collects one or more inputs from one or more input sources, e.g., an input device 360, a LUT 370, and a circuit design 380. For example, with further reference to FIG. 2, the input device 360 accepts one or more specifications that includes: the predetermined mismatch threshold (Threshold_{MM}), the input current (I_{IN}), the number (N_{CMC}) of current mirror circuits in the semiconductor chip, and the chip defect level (J) of the semiconductor chip. The input device 360 then transmits these specifications to the receiver 310.

The predetermined mismatch threshold (Threshold_{MM}), e.g., expressed as a percentage (such as 5%), represents the maximum mismatch value (M_{V2}) between the input and output currents (I_{IN}, I_{OUT}). That is, when the mismatch value (M_{V2}) exceeds the predetermined mismatch threshold (Threshold_{MM}), it indicates that the output current (I_{OUT}) significant deviates of the input current (I_{IN}), implying that the current mirror circuit 200 is inaccurately replicating the input current (I_{IN}). Conversely, when the mismatch value (M_{V2}) is within the predetermined mismatch threshold (Threshold_{MM}), the output current (I_{OUT}) closely duplicates the input current (I_{IN}), suggesting reliable performance and adherence to desired specifications by the current mirror circuit 200.

The extractor 320 extracts one or more parameters from a circuit design 380, which corresponds to the current mirror circuit 200, and transmits the parameters extracted thereby to the receiver 310. For example, these parameters include the channel width (W), the gate length (L), and the ratio (R) of the output current (I_{OUT}) to the input current (I_{IN}).

The retriever 330 retrieves one or more predetermined constants, e.g., predetermined constants (μₙC_{OX}, G), from the LUT 370 and transmits the predetermined constants (μₙC_{OX}, G) retrieved thereby to the receiver 310. In summary, as shown in Table 2 below, the receiver 310 receives the specifications (e.g., the predetermined mismatch threshold Threshold_{MM}, the input current I_{IN}, the number N_{CMC} of current mirror circuits in the semiconductor chip, and the chip defect level J of the semiconductor chip) from the input device 360, the parameters (e.g., the channel width W, the gate length L, and the ratio R) from the extractor 320, and the predetermined constants (μₙC_{OX}, G) from the retriever 330.

TABLE 2

| Notation | Description | Input Source |
|---|---|---|
| Threshold_{MM} | predetermined mismatch threshold | input device |
| I_{IN} | input current | input device |
| N_{CMC} | number of current mirror circuits in a chip | input device |
| J | chip defect level of a chip | input device |
| W | channel width, (m)(N_{fingers})(w) | circuit design |
| L | gale length, (N_{stack})(Ig) | circuit design |
| R | current ratio | circuit design |
| μₙC_{OX} | predetermined constant | LUT |
| G | predetermined constant | LUT |

The receiver 310 transmits the specifications (Threshold_{MM}, I_{IN}, N_{CMC}, J), the parameters (W, L, R), and the predetermined constants (μₙC_{OX}, G) that it received from the input device 360, the extractor 320, and the retriever 330 to the calculator 340. The calculator 340 computes a mismatch value (M_{V2}) based on these metrics (I_{IN}, N_{CMC}, J, W, L, R, μₙC_{OX}, G) using Equation (13):

$${M}_{V 2} = {( 1 + \frac{Δ {V}_{TH}}{\sqrt{\frac{{I}_{IN}}{{μ}_{n} {C}_{OX} \frac{W}{L}}}} )}^{2} - 1 where \qquad ( 13 )$$

$$Δ {V}_{TH} = NORMINV ( ( 1 - ( 1 - J / 1 e 6 ) \hat{} ( 1 / {N}_{CMC} ) ) / 2 , 0 , 1 ) ( \frac{G}{\sqrt{WL}} ) \sqrt{R + 1}$$

NORMINV is a MS Excel function that returns the inverse of the normal cumulative distribution for the specified mean and standard deviation. Equation (13) can be derived from Equations (1), (3), and (4). For example, by rearranging Equation (1), Equation (8) is obtained.

Substituting Equation (1) into Equation (4) yields:

$${M}_{V 2} = \frac{{μ}_{n} {C}_{OX} \frac{W}{L} {( {V}_{GS} - {V}_{TH 2} )}^{2}}{{μ}_{n} {C}_{OX} \frac{W}{L} {( {V}_{GS} - {V}_{TH 1} )}^{2}} - 1 \qquad ( 14 )$$

By cancelling the predetermined constant (μₙC_{OX}), Equation (10) is obtained as follows:

$${M}_{V 2} = \frac{{( {V}_{GS} - {V}_{TH 2} )}^{2}}{{( {V}_{GS} - {V}_{TH 1} )}^{2}} - 1 \qquad ( 15 )$$

Substituting Equation (3) into Equation (15) results in:

$${M}_{V 2} = \frac{{( {V}_{GS} - {V}_{TH 1} + Δ {V}_{TH} )}^{2}}{{( {V}_{GS} - {V}_{TH 1} )}^{2}} - 1 \qquad ( 16 )$$

Simplifying Equation (11) yields:

$${M}_{V 2} = {( 1 + \frac{Δ {V}_{TH}}{{V}_{GS 1} - {V}_{TH 1}} )}^{2} - 1 \qquad ( 17 )$$

Finally, inserting Equation (8) into Equation (17) results in Equation (13).

The receiver 310 transmits the specification (Threshold_{MM}) received thereby from the input device 360 to the comparator 350. The calculator 340 transmits the mismatch value (M_{V2}) that it calculated to the comparator 350. The comparator 350 then compares the mismatch value (M_{V2}) to the predetermined mismatch threshold (Threshold_{MM}) and generates a comparison result. The output device 390 indicates whether there is a mismatch between input and output currents (I_{N}, I_{OUT}) based on the comparison result. For example, in some embodiments, the output device 390 is a computer monitor. In such some embodiments, if the mismatch value (M_{V2}) is greater than the predetermined mismatch threshold (Threshold_{MM}), the output device displays “FAIL.” Otherwise, a “Pass” is displayed by the output device 390. In other embodiments, the output device 390 may be a computer speaker, a computer printer, other output devices capable of indicating the comparison result, or combinations thereof.

With further reference to Table 3 below, the defect level (J) of chips per million parts can be determined by several factors, including chip yield or the percentage of chips that are defect-free, the yield of current mirror circuits of a chip, the number of defects per million in the current mirror circuit, and the desired number of sigma (σ), or standard deviations, for the current mirror circuit quality.

TABLE 3

| chip defect | chip | | | # of sigma desired, per CMC |
|---|---|---|---|---|
| level (ppm) | yield | CMC yield* | CMC defect (ppm)* | NORM.INV((1 − (1 − J/1e6)\hat{ }(1/ |
| J | 1 − J/1e6 | (1 − J/1e6)\hat{ }(1/N_{CMC}) | (1 − (1 − J/1e6)\hat{ }(1/N_{CMC})*1e6 | N_{CMC})/2, 0, 1) |
| 10 | 0.99999 | 0.99999900 | 1.00 | 4.89* |
| 100 | 0.9999 | 0.99999000 | 10.00 | 4.42* |
| 1000 | 0.999 | 0.99989995 | 100.05 | 3.89* |
| 10000 | 0.99 | 0.99899547 | 1004.53 | 3.29* |

*e.g., 10 current mirror circuits in a chip

The chip yield is calculated as:

$$1 - \frac{J}{{10}^{6}} \qquad ( 18 )$$

The yield for the current mirror circuits is calculated as:

$${( 1 - \frac{J}{{10}^{6}} )}^{1 / {N}_{CMC}} \qquad ( 19 )$$

The defects per million in the current mirror circuits is calculated as:

$${( 1 - \frac{J}{{10}^{6}} )}^{1 / {N}_{CMC}} ) \times 1 {0}^{6} \qquad ( 20 )$$

The desired quality level for the current mirror circuits is derived using the inverse normal distribution function.

For example, as can be seen from Table 3 above, achieving a chip yield of 0.99999 corresponds to a chip defect level (J) of 10. Conversely, a lower current mirror circuit yield, e.g., 0.99899547, results in a higher chip defect level (J), e.g., 10000. The chip defect level (J) is proportional to the number of defective current mirror circuits. Additionally, a higher number of sigma (σ) values indicates a lower chip defect level (J), reflecting higher quality and lower defect rates.

The data reveals that as the chip defect level (J) increases, both the chip yield and current mirror circuit yield decrease. Conversely, the current mirror circuit defect rate rises with higher chip defect levels (J). Additionally, the number of sigma (σ) desired per current mirror circuit decreases as the chip defect level (J) increases, suggesting that higher defect levels (J) lead to lower quality circuits. For instance, with a chip defect level (J) of 10 ppm, the chip yield is 0.99999 and the current mirror circuit yield is 0.99999900, resulting in a current mirror circuit defect rate of 1.00 ppm and a sigma (σ) value of 4.89. However, at a defect level (J) of 10,000 ppm, the chip yield drops to 0.99 and the current mirror circuit yield to 0.99899547, resulting in a current mirror circuit defect rate of 1004.53 ppm and a sigma (σ) value of 3.29. This highlights the impact of defect levels (J) on overall chip and circuit quality.

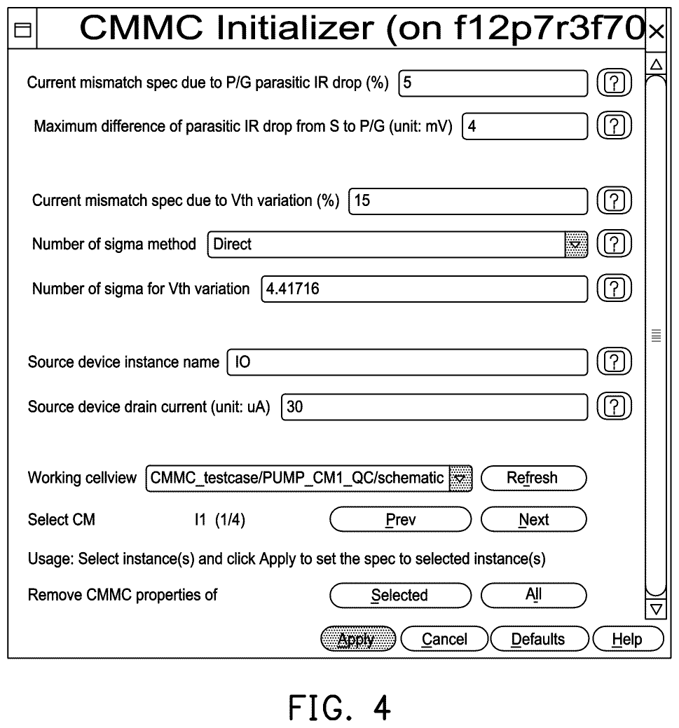

FIG. 4 is a schematic diagram illustrating an exemplary GUI (Graphical User Interface) 400 of the system 100 in accordance with various embodiments of the present disclosure. The GUI 400 enables users to interact with the system 100 through graphical elements such as windows, text boxes and buttons, rather than text-based commands. As illustrated in FIG. 4, the window is a rectangular area on the screen that displays content on the output device 390 and can be resized, minimized, maximized, or closed. The text box allows users to enter text input for data entry, while the button is labeled with text and performs actions when pressed. For example, the GUI 400 includes fields for accepting the specifications e.g., Source_{MM}, ΔV_{S}, I_{IN}, Threshold_{MM}, ΔV_{TH}, N_{CMC}, and J, as inputs in its text boxes. Users interact with the GUI 400 using input devices like a computer mouse, computer keyboard, or touchscreen, with the GUI 400 providing visual and auditory feedback.

An exemplary LUT 370, i.e., Table 4, shows the relationship between transistor characteristics (such as those of master/slave transistor 210, 220) and the predetermined constants (μₙC_{OX}, G). As can been seen, each row in Table 4 includes a distinct combinations of channel width (W) of the master/slave transistor 210, 220, gate length (L) the master/slave transistor 210, 220, and predetermined constants (μₙC_{OX}, G). For example, one row specifies a channel width (W) of 32 nm, a gate length (L) of 3 nm, a predetermined constant (μₙC_{OX}) of 3.75357812594852E-05, and a predetermined constant (G) of 0.143066564361755. In the subsequent sections, further details will explain how the LUT 370, e.g., Table 4, is generated, such as by a device external to the system 110 or by the system 110 itself.

TABLE 4

| cell | device | width | length | [symbol] | G |
|---|---|---|---|---|---|
| DFB_H156_MOS_R1 | [symbol] | 32n | 3n | 3.75357812594852E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R1 | [symbol] | 32n | 3n | [symbol] E−05 | 0. [symbol] |
| DFB_H156_MOS_R2 | [symbol] | 32n | 3n | [symbol] E−05 | 0. [symbol] |
| DFB_H156_MOS_R2 | [symbol] | 32n | 3n | [symbol] E−05 | 0. [symbol] |
| DFB_H156_MOS_R2 | [symbol] | 32n | 3n | [symbol] E−05 | 0. [symbol] |
| DFB_H156_MOS_R2 | [symbol] | 32n | 3n | [symbol] E−05 | 0. [symbol] |

[symbol]

indicates data missing or illegible when filed

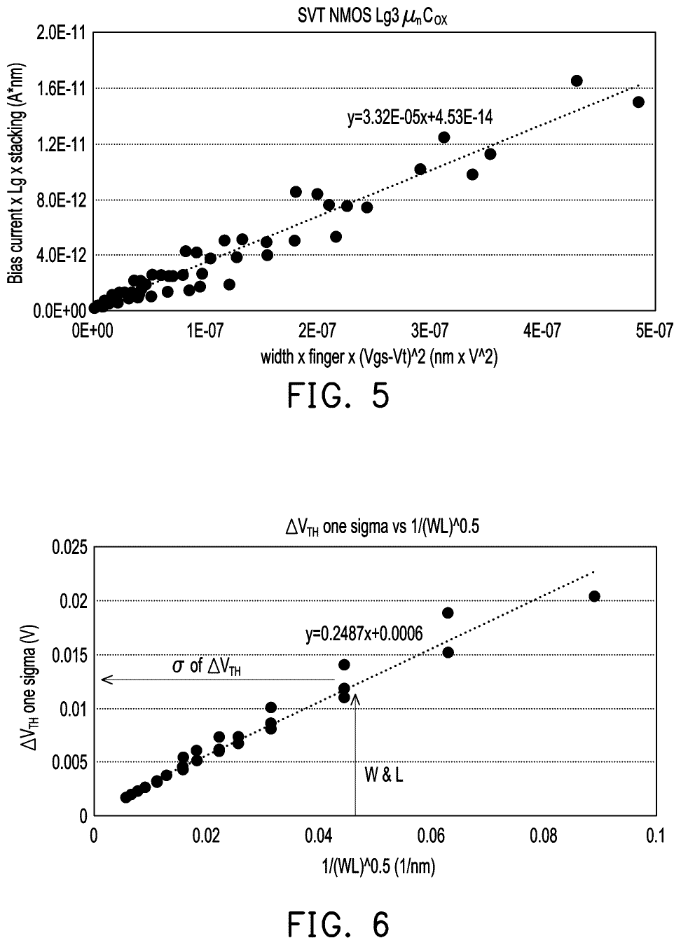

FIG. 5 is a plot illustrating an exemplary relationship between parameters of the master transistor 210 in accordance with various embodiments of the present disclosure. As illustrated in FIG. 5, the x-axis represents the product of channel width (w) of the master transistor 210, the number (N_{finger}) of fingers of the gate region of the master transistor 210, and (V_{GS}−V_{TH})², where V_{GS} is the gate-source voltage of the master transistor and V_{TH} is the threshold voltage of the master transistor. The y-axis represents the product of input current (I_{IN}), gate length (Lg) of the master transistor 210, and The number (N_{stack}) of channel region of the master transistor 210. The dotted line, described by the equation y=3.32E−5x+4.53E-14, indicates a linear relationship between the variables. The slope of this trend line is influenced by the predetermined constant (μnCox). The predetermined constants (μnCox) obtained from this graph are mapped to the LUT 370. For example, Equation (21) for calculating the predetermined constants (μnCox) can be derived from Equation (1):

$${µ}_{n} {C}_{OX} = \frac{{I}_{IN} ( L )}{{W ( {V}_{GS} - {V}_{TH} )}^{2}} \qquad ( 21 )$$

FIG. 6 is a plot illustrating an exemplary relationship between parameters of the master transistor 210 in accordance with various embodiments of the present disclosure. As illustrated in FIG. 6, the x-axis represents 1/(WL)^{0.5}, where W is the channel width of the master transistor 210 and L is the gate length of the master transistor 210, both measured in nanometers. The y-axis represents the ΔV_{TH} one sigma (σΔV_{TH}), which is the standard deviation of threshold voltage variation in Volts. The ΔV_{TH} one sigma (σΔV_{TH}) is defined by Equation (22):

$$σ {V}_{TH} = \frac{G}{\sqrt{WL}} \qquad ( 22 )$$

The dotted line, on the graph represents a linear fit through the data points, and the equation “y=0.2487x+0.0006” further illustrates this trend. The slope of this trend line is influenced by the predetermined constant (G). The predetermined constants (G) obtained from this graph are mapped to the LUT 370. For example, Equation (23) for calculating the predetermined constants (G) can be derived from Equation (22):

$$G = σ {V}_{TH} \sqrt{WL} \qquad ( 23 )$$

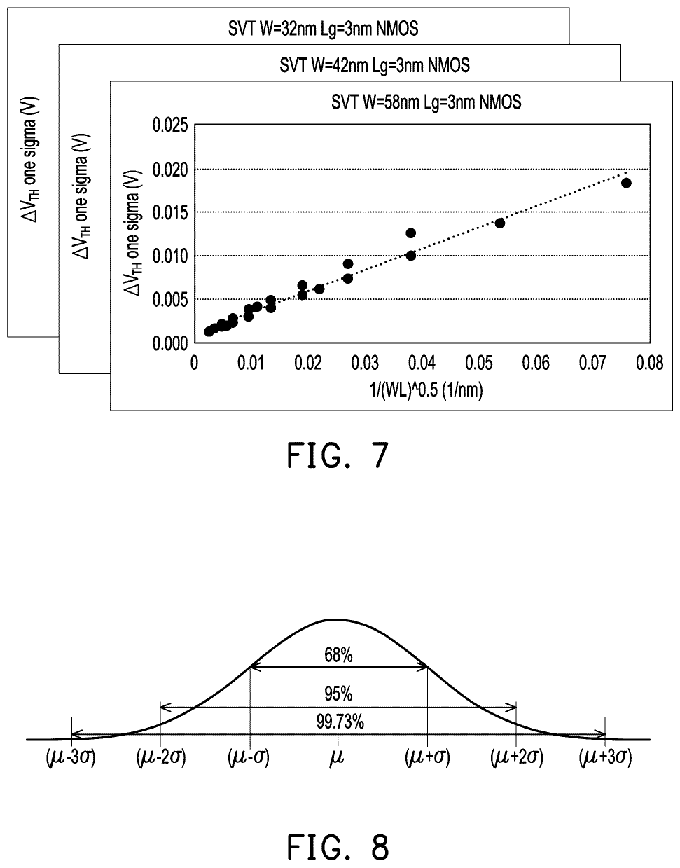

FIG. 7 is a plot illustrating another exemplary relationship between parameters of the master transistor 210 in accordance with various embodiments of the present disclosure. As illustrated in FIG. 7, the three overlaid graphs, each representing data for the master transistor 210 with a gate length (Lg) of 3 nm but different widths (W). The top graph corresponds to a width of 32 nm, the middle graph to 42 nm, and the bottom graph to 58 nm. Each graph shows the relationship between the standard deviation of the ΔV_{TH} one sigma (σΔV_{TH}) and the reciprocal of the square root of the product of the channel width and length of the master transistor 210, i.e., 1/(WL)^{0.5}. The slope of the trend line of each graph is influenced by the predetermined constant (G). The predetermined constants (G) obtained from these graphs are mapped to the LUT 370.

In some embodiments, the predetermined constants (μₙC_{OX}, G) are obtained from the same voltage threshold, e.g., standard voltage threshold (SVT), and across various combinations of channel width (W) and gate length (L). In other embodiments, with reference to Table 5, the predetermined constants (μₙC_{OX}, G) are obtained from different combinations of voltage thresholds, including SVT, LVT (low voltage threshold), uLVT (ultra-low voltage threshold), channel width (W), and gate length (L).

TABLE 5

| Device type | Device list | W | L |
|---|---|---|---|
| NMOS | svt, lvt, ulvt . . . | 32n, 42n, 58n | 3n, 22n |
| PMOS | svt, lvt, ulvt . . . | 32n, 42n, 58n | 3n, 22n |

FIG. 8 is a plot illustrating an exemplary sigma (σ) level in accordance with various embodiments of the present disclosure. As illustrated in FIG. 8, the example graph is a standard normal distribution curve, also known as a bell curve, which is often used in the context of sigma levels to describe variability in manufacturing processes and to predict manufacturing yield. For example, the horizontal axis represents the range of values around the mean (μ) of the distribution, labeled in terms of standard deviations (σ) from the mean, showing points at μ−3σ, μ−2σ, μ−1σ, μ, μ+1σ, μ+2σ, and μ+3σ. The vertical axis represents the probability density or frequency of occurrences of these values. The areas under the curve indicate that 68% of the data falls within +1σ (one standard deviation) of the mean, implying that in a manufacturing process, about 68% of the parts produced will meet the specification if they fall within this range. Similarly, 95% of the data falls within ±2σ (two standard deviations), indicating a higher yield of 95%, and 99.73% falls within ±3σ (three standard deviations), meaning substantially all (99.73%) parts produced will meet the specification within this range.

In the context of sigma levels for manufacturing yield, operating at a lo level means only 68% of the products meet specifications, indicating a high defect rate. At 2σ, 95% of the products meet specifications, which is an improvement but may still not be acceptable in high-precision industries. At 3σ, 99.73% of the products meet specifications, reducing defects significantly. Higher sigma levels, such as 4σ, 5σ, and 6σ, indicate even fewer defects, with 4σ achieving about 99.9937% yield, 5σ achieving about 99.99994% yield, and 6σ achieving about 99.9999998% yield, which is nearly defect-free and the goal of Six Sigma methodology aimed at near-perfect quality. This graph underscores the importance of minimizing variability and improving process capability to achieve higher sigma levels, leading to better chip quality.

Table 6 shows the relationship between target chip defect rates, target chip yields, corresponding sigma levels, and the required tolerance for threshold voltage variation (ΔV_{TH}). For example, for a stringent target chip defect rate of ≤100 ppm, achieving a very high yield of ≥99.99%, which requires a sigma level of ≥3.89 and allows for a significant threshold voltage variation (ΔV_{TH}) tolerance (++++). As the defect rate target becomes more lenient, such as ≤1000 ppm, the target yield decreases to ≥99.90%, the required sigma level drops to ≥3.29, and threshold voltage variation (ΔV_{TH}) tolerance remains high (+++). For a target defect rate of ≤2700 ppm, a yield of ≥99.73% is achievable with a sigma level of ≥3.00 and moderate threshold voltage variation (ΔV_{TH}) tolerance (++). The least stringent target defect rate of ≤10000 ppm corresponds to a yield of ≥99.00%, requiring a sigma level of ≥2.58 and lower threshold voltage variation (ΔV_{TH}) variation tolerance (+). That is, Table 7 underscores the trade-offs in manufacturing processes between achieving high yields, maintaining low defect rates, and managing variability in threshold voltage.

TABLE 6

| Target chip | | Number of | |
|---|---|---|---|
| defect | Target chip | sigma to | ΔVₜₕ |
| (ppm) | yield | cover | variation |
| ≤100 | ≥99.99% | ≥3.89 | ++++ |
| ≤1000 | ≥99.90% | ≥3.29 | +++ |
| ≤2700 | ≥99.73% | ≥3.00 | ++ |
| ≤10000 | ≥99.00% | ≥2.58 | + |

Table 7 details how the number of current mirror circuits in a semiconductor chip affects the yield requirements for both the semiconductor chip and the individual current mirror circuits, alongside the tolerance for threshold voltage variation (ΔV_{TH}). It presents scenarios for chips with 1, 10, and 100 current mirror circuits, each aiming for a consistent target chip yield of 99%. As the number of current mirror circuits in a semiconductor chip increases, the yield requirement for each individual current mirror circuit becomes stricter. Specifically, a chip with 1 current mirror circuit requires a 99% yield for that circuit, allowing for lower tolerance in threshold voltage variation (ΔV_{TH}) tolerance (+). In contrast, a chip with 10 current mirror circuits demands a 99.9% yield for each circuit, necessitating moderate threshold voltage variation (ΔV_{TH}) tolerance (++). For chips with 100 current mirror circuits, the yield requirement for each circuit escalates to 99.9999%, requiring a high tolerance for threshold voltage variation (ΔV_{TH}) tolerance (+++). This illustrates the balance between yield, variability, and process control in complex semiconductor chip designs, emphasizing the need for stringent control as the complexity and number of current mirror circuits in the semiconductor chip increase to maintain the desired overall yield.

TABLE 7

| Number of CM | Target chip | Each CM yield | ΔVₜₕ |
|---|---|---|---|
| in whole chip | yield | requirement | Variation |
| 1 | 99% | 99% | + |
| 10 | 99% | 99.9% | ++ |
| 100 | 99% | 99.9999% | +++ |

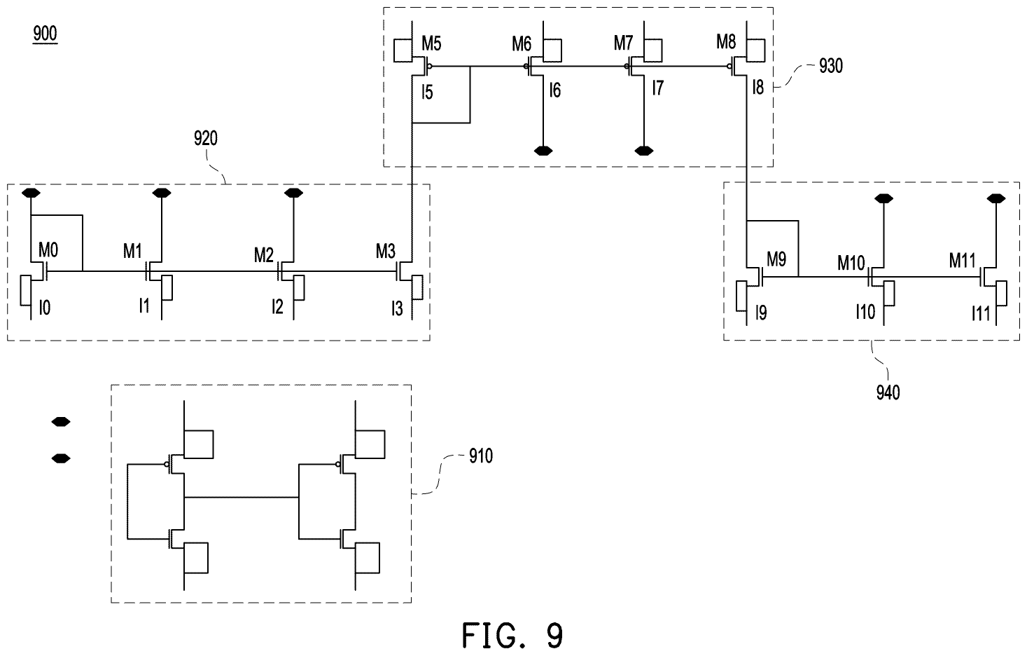

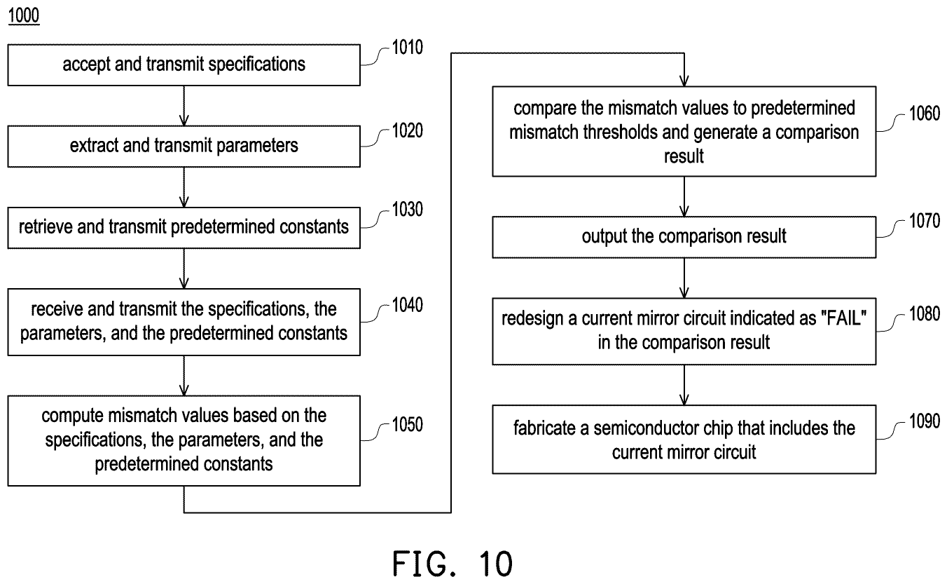

Example supporting circuitry for a semiconductor chip 900 is depicted in FIG. 9. It is understood that this circuitry is provided by way of example, not by limitation, and other suitable system circuitry are within the scope of the present disclosure. FIG. 9 is a schematic circuit diagram illustrating an exemplary a semiconductor chip 900 in accordance with various embodiments of the present disclosure. As illustrated in FIG. 9, the example semiconductor chip 900 includes a current-driven circuit 910 and one or more current mirror circuits 920-940. The current-driven circuit 910 is connected to at least one of the current mirror circuits 920-940 and performs a predetermined circuit function. In certain embodiments, the current-driven circuit 910 includes a voltage regulator, a bandgap reference circuit, other circuits that rely on a current generated by at least one of the current mirror circuits 920-940, or combinations thereof.

Each current mirror circuit 920-940 includes a master transistor (M0, M5, M9) and one or more slave transistors (M1-M3, M6-M8, M10, M11) connected to the master transistor (M0, M5, M9). The master transistor (M0, M5, M9) allows an input current (I0, I5, I9), e.g., associated with a current generated by a current source or a current of another current mirror circuit, to flow therethrough. Each slave transistor (M1-M3, M6-M8, M10, M11) generates an output current (I1-I3, I6-I8, I10, I11) that is a duplicate, a multiple, or a fraction) of the input current (I0, I5, I9).

In an exemplary operation, with further reference to FIG. 3, when it is desired to confirm whether there is a mismatch between the input and output currents (I0, I5, I9, I1-I3, I6-I8, I10, I11) of the current mirror circuit 720-740, the receiver 310 receives specifications from the input device 360. These specifications include the predetermined mismatch thresholds (Source_{MM}, Threshold_{MM}), the voltage difference (ΔV_{S}), the input current (I0, I5, I9), and the number (N_{CMC}) of current mirror circuits in the semiconductor chip, and the chip defect level (J) of the semiconductor chip. At this time, the output device 390 displays an output, e.g., Table 8. As can be seen from Table 8, the predetermined mismatch thresholds (Source_{MM}, Threshold_{MM}) are expressed in percentages, e.g., 5% and 15%, respectively.

TABLE 8

| | | | | Predetermined | Mismatch | Predetermined | Mismatch | Vth | | |
|---|---|---|---|---|---|---|---|---|---|---|
| Slave | Master | Current | Slave Current | Threshold | Value | threshold | Value | Variation | | Pass/ |
| Current | Current | Ratio | Value (uA) | (source [symbol] ) | (M [symbol] ) | (threshold [symbol] ) | (M [symbol] ) | ( [symbol] ) | | Fail |
| I1 | I0 | 2 | 60 | 5% | 2.988% | 15% | 12.528% | 1 [symbol] .400 | mV: | Pass |
| I2 | I0 | 1 | 30 | 5% | 2.988% | 15% | 14.533% | 18.937 | mV | Pass |
| I3 | I0 | 2 | 60 | 5% | 2.988% | 15% | 12.528% | 1 [symbol] .400 | mV | Pass |
| I6 | I5 | 1 | 30 | 5% | 4.290% | 15% | 17.229% | 15.589 | mV | Fail |
| I7 | I5 | 0.5 | 15 | 5% | 4.290% | 15% | 21.289% | 19.093 | mV | Fail |
| I8 | I5 | 1 | 30 | 5% | 4.290% | 15% | 17.229% | 15.589 | mV | Fail |
| I10 | I9 | 1 | 30 | 5% | 2.657% | 15% | 10.813% | 15.858 | mV | Pass |
| I11 | I9 | 1 | 30 | 5% | 2.675% | 15% | 10.813% | 15.858 | mV | Pass |

[symbol]

indicates data missing or illegible when filed

Subsequently, the extractor 320 extracts parameters from a circuit design 380, which corresponds to the semiconductor chip 900, and transmits the parameters extracted thereby to the receiver 310. For example, these parameters include the channel widths (W) of the master and slave transistors (M0-M11), the gate lengths (L) of the master and slave transistors (M0-M11), and the ratio (R) of the output current (I1-I3, I6-I8, I10, I11) to the input current (I0, I5, I9). For example, Table 8 shows that the ratio (R) of the output current (I0) to the input current (I1, I3) is two. That is, the output current (I0) is a multiple, e.g., substantially twice, the input currents (I1, I3). The ratio (R) of the output current (I0, I5, I9) to the input current (I2, I6, I8, I10, I11) is one, i.e., the output current (I0, I5, I9) is substantially equal to the input current (I2, I6, I8, I10, I11). The output current (I5) is a fraction of, e.g., substantially half, the input current (I7) and the ratio (R) of the output current (I5) to the input current (I7) is therefore 1:2.

Next, the retriever 330 retrieves predetermined constants, e.g., the predetermined constant (μₙC_{OX}, G), from the LUT 370 and transmits the predetermined constants (μₙC_{OX}, G) retrieved thereby to the receiver 310. The receiver 310 then transmits the specifications (ΔV_{S}, I_{IN}, N_{CMC}, J), the parameters (W, L, R), and the predetermined constants (μₙC_{OX}, G) that it received from the input device 360, the extractor 320, and the retriever 330 to the calculator 340. The calculator 340 computes a mismatch value (M_{V1}, M_{V2}) based on these metrics (I_{IN}, N_{CMC}, J, W, L, R, μₙC_{OX}, G) using Equations (7) and (13).

The receiver 310 transmits the specification (Source_{MM}, Threshold_{MM}) received thereby from the input device 360 to the comparator 350. The calculator 340 transmits the mismatch value (M_{V1}, M_{V2}) that it calculated to the comparator 350. The comparator 350 then compares the mismatch value (M_{V1}, M_{V2}) to the predetermined mismatch threshold (Source_{MM}, Threshold_{MM}) and generates a comparison result, e.g., Table 8. The output device 390 indicates whether there is a mismatch between input and output currents (I_{N}, I_{OUT}) based on the comparison result. For example, as shown in Table 8, because the mismatch values (M_{V1}, M_{V2}) between the input current (I0, I9) and the output current (I1-I3, I10, I11) are within the predetermined mismatch thresholds (Source_{MM}, Threshold_{MM}), respectively, the current mirror circuit 720, 740 is indicated as “Pass.” Conversely, because the mismatch value (M_{V1}, M_{V2}) between the input current (I5) and the output current (I6-I8) exceeds the predetermined mismatch threshold (Source_{MM}, Threshold_{MM}), the current mirror circuit 730 is indicated as “Fail.”

FIG. 10 is a flowchart of an exemplary method 1000 of checking mismatches in current mirror circuits, e.g., current mirror circuits 920-940, of a semiconductor chip, e.g., semiconductor chip 900, in accordance with various embodiments of the present disclosure. The example method 1000 will now be described with further reference to FIGS. 1-9 for ease of understanding. It is understood that the method 1000 is applicable to structures other than those of FIGS. 1-9. Further, it is understood that additional operations can be provided before, during, and after the method 1000, and some of the operations described below can be replaced or eliminated, in an alternative embodiment of the method 1000.

In operation 1010, the input device 360 accepts predetermined mismatch thresholds (Source_{MM}, Threshold_{MM}), a voltage difference (ΔV_{S}), an input current (I0, I5, I9), and the number (N_{CMC}) of the current mirror circuits 920-940 in the semiconductor chip 900, and the chip defect level (J) of the semiconductor chip 900. It then transmits these specifications to the receiver 310. In operation 1020, the extractor 320 extracts the channel widths (W) of the master and slave transistors (M0-M11), the gate lengths (L) of the master and slave transistors (M0-M11), and the ratio (R) of the output current (I1-I3, I6-I8, I10, I11) to the input current (I0, I5, I9) from a circuit design 380, which corresponds to the semiconductor chip 900. These parameters are then sent to the receiver 310.

In operation 1030, the retriever 330 retrieves predetermined constants (μₙC_{OX}, G) from the LUT 370 and forwards to the receiver 310. In an alternative embodiment, the method 1000 further includes generating, e.g., by a LUT generator external to the system 110 or by the retriever 330, the LUT 370, e.g., Table 4, prior to operation 1030. In operation 1040, the receiver 310 transmits the specifications (ΔV_{S}, I_{IN}, N_{CMC}, J), the parameters (W, L, R), and the predetermined constants (μₙC_{OX}, G) received from the input device 360, the extractor 320, and the retriever 330 to the calculator 340. At this time, the receiver 310 also sends the specification (Source_{MM}, Threshold_{MM}) to the comparator 350.

In operation 1050, the calculator 340 computes mismatch values (M_{V1}, M_{V2}) based on the metrics (I_{IN}, N_{CMC}, J, W, L, R, μₙC_{OX}, G) using Equations (7) and (13) and transmits the mismatch values (M_{V1}, M_{V2}) that it calculated to the comparator 350. In operation 1060, the comparator 350 compares the mismatch values (M_{V1}, M_{V2}) to the predetermined mismatch thresholds (Source_{MM}, Threshold_{MM}) and generates a comparison result. In operation 1070, the output device 390 displays the comparison result, e.g., Table 9. In operation 1080, the current mirror circuits indicated as “FAIL” in the comparison result, e.g., current mirror circuit 930, are redesigned or optimized to decrease the mismatch between the input and output currents (I5, I6-I8) thereof. In operation 1090, the semiconductor chip 900 is fabricated based on the optimized current mirror circuit 930.

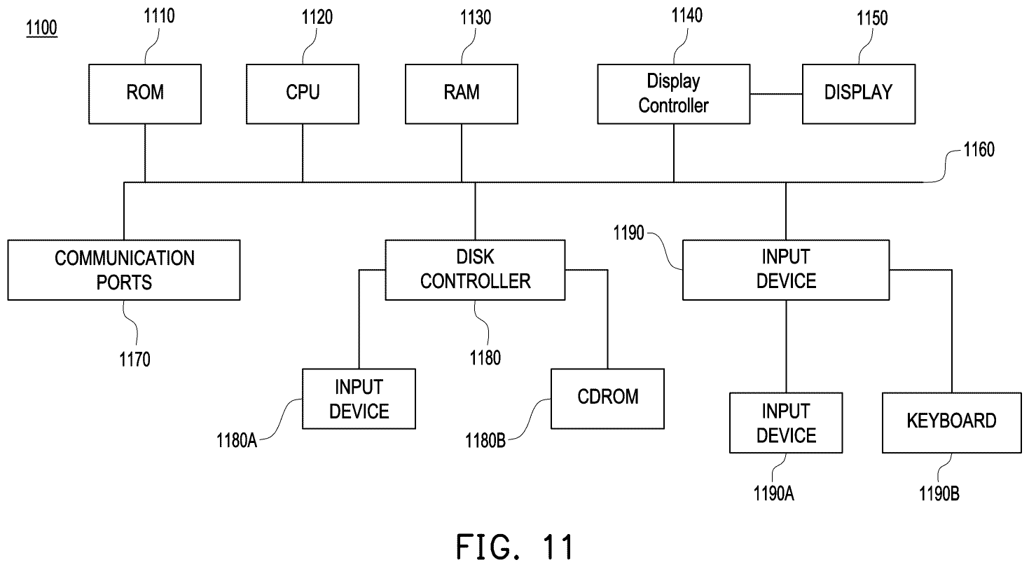

FIG. 11 is a schematic block diagram illustrating an exemplary computing device architecture in accordance with various embodiments of the present disclosure. The example computing device architecture 1100 may be employed to implement the system 110 described herein. As illustrated in FIG. 11, a bus 1160 can serve as the information highway interconnecting the other illustrated components of the hardware. A processing system 1120 labeled CPU (central processing unit) (e.g., one or more computer processors/data processors at a given computer or at multiple computers), can perform calculations and logic operations required to execute a program. A non-transitory processor-readable storage medium, such as read only memory (ROM) 1110 and random access memory (RAM) 1130, can be in communication with the processing system 1120 and can include one or more programming instructions for the operations specified here. Optionally, program instructions can be stored on a non-transitory computer-readable storage medium such as a magnetic disk, optical disk, recordable memory device, flash memory, or other physical storage medium.

In one example, a disk controller 1180 can interface one or more optional disk drives to the system bus 1160. These disk drives can be external or internal CD-ROM, CD-R, CD-RW or DVD, or solid state drives such as 1180B, or external or internal hard drives 1180A. As indicated previously, these various disk drives 1180A, 1180B and disk controllers are optional devices. The system bus 1160 can also include at least one communication port 1170 to allow for communication with external devices either physically connected to the computing system or available externally through a wired or wireless network. In some cases, the communication port 1170 includes or otherwise comprises a network interface.

To provide for interaction with a user, the subject matter described herein can be implemented on a computing device having a display device 1150 (e.g., a CRT (cathode ray tube) or LCD (liquid crystal display) monitor) for displaying information obtained from the bus 1160 to the user and an input device 1190A such as keyboard 1190B and/or a pointing device (e.g., a mouse or a trackball) and/or a touchscreen by which the user can provide input to the computer. Other kinds of input devices 1190A can be used to provide for interaction with a user as well; for example, feedback provided to the user can be any form of sensory feedback (e.g., visual feedback, auditory feedback by way of a microphone or tactile feedback); and input from the user can be received in any form, including acoustic, speech, or tactile input. In the input device 1190A and the keyboard 1190B can be coupled to and convey information via the bus 1160 by way of an input device interface 1190A. Other computing devices, such as dedicated servers, can omit one or more of the display 1150 and display interface 1140, the input device 1190A, the keyboard 1190B, and input device interface 1190.

In an embodiment, a method comprising: receiving a predetermined mismatch threshold, a voltage difference, an input current of a circuit associated with a first transistor, a channel width of the first transistor, a gate length of the first transistor, and a predetermined constant; calculating a mismatch value between a second current associated with a second transistor of the circuit and the first current based on the voltage difference, the input current, the channel width, the gate length, and the predetermined constant; and comparing the mismatch value to the predetermined mismatch threshold and generating a comparison result that specifies whether the mismatch value exceeds the predetermined mismatch threshold. The parameter associated with the first transistor or the second transistor is modified when the mismatch value exceeds the predetermined mismatch threshold. A device is fabricated based on the modified parameter.

In another embodiment, a system comprises a receiver, a calculator, and a comparator. The receive collects a predetermined mismatch threshold, a voltage difference between a source voltage of a master transistor of a current mirror circuit and a source voltage of a slave transistor of the current mirror circuit, an input current associated with the master transistor, a channel width of the master transistor, a gate length of the master transistor, and a predetermined constant. The calculator computes a mismatch value between an output current associated with the slave transistor and the input current based on the voltage difference, the input current, the channel width, the gate length, and the predetermined constant. The comparator compares the mismatch value to the predetermined mismatch threshold and generates a comparison result that specifies whether the mismatch value exceeds the predetermined mismatch threshold.

In another embodiment, a system comprises a receiver, a calculator, and a comparator. The receiver collects a predetermined mismatch threshold, an input current associated with a master transistor of a current mirror circuit, a number of current mirror circuits in a semiconductor chip, a chip defect level of the semiconductor chip, a channel width of the master transistor, a gate length of the master transistor, and first and second predetermined constants. The calculator computes a mismatch value between an output current associated with a slave transistor of the current mirror circuit and the input current based on a voltage difference, the input current, the channel width, the gate length, and the first and second predetermined constants. The comparator compares the mismatch value to the predetermined mismatch threshold and generates a comparison result that specifies whether the mismatch value exceeds the predetermined mismatch threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
receiving a predetermined mismatch threshold, a voltage difference, an input current associated with a master transistor of a current mirror circuit, a channel width of the master transistor, a gate length of the master transistor, and a first predetermined constant;
calculating a mismatch value between an output current associated with a slave transistor of the current mirror circuit and the input current based on the voltage difference, the input current, the channel width, the gate length, and the first predetermined constant; and
comparing the mismatch value to the predetermined mismatch threshold and generating a comparison result that specifies whether the mismatch value exceeds the predetermined mismatch threshold;
wherein a parameter associated with the master or slave transistor is modified when the mismatch value exceeds the predetermined mismatch threshold, wherein a device is fabricated based on the modified parameter.

2. The method of claim 1, wherein the voltage difference is associated with a source voltage of the current mirror circuit.

3. The method of claim 1, further comprising receiving a number of current mirror circuits in a semiconductor chip, a chip defect level of the semiconductor chip, and a second predetermined constant, wherein the voltage difference is associated with the chip defect level, the number of current mirror circuits, the channel width, the gate length, and a ratio of the output current to the input current.

4. The method of claim 1, further comprising extracting the channel width and the gate length from a circuit design.

5. The method of claim 1, further comprising retrieving the first predetermined constant from a look-up table (LUT).

6. A system comprising:
a receiver configured to collect:
a predetermined mismatch threshold;
a voltage difference between a source voltage of a master transistor of a current mirror circuit and a source voltage of a slave transistor of the current mirror circuit;
an input current associated with the master transistor;
a channel width of the master transistor;
a gate length of the master transistor; and
a predetermined constant;
a calculator configured to compute a mismatch value between an output current associated with the slave transistor and the input current based on the voltage difference, the input current, the channel width, the gate length, and the predetermined constant; and
a comparator configured to compare the mismatch value to the predetermined mismatch threshold and to generate a comparison result that specifies whether the mismatch value exceeds the predetermined mismatch threshold.

7. The system of claim 6, wherein the receiver is configured to receive the predetermined mismatch threshold, the voltage difference, and the input current from an input device.

8. The system of claim 6, further comprising an extractor configured to extract the channel width and the gate length from a circuit design and to transmit the channel width and the gate length extracted thereby to the receiver.

9. The system of claim 6, further comprising a retriever configured to retrieve the predetermined constant from a look-up table (LUT) and to transmit the predetermined constant retrieved thereby to the receiver.

10. The system of claim 9, further comprising the LUT.

11. The system of claim 9, wherein the retriever is further configured to generate the LUT.

12. The system of claim 6, further comprising a user interface configured to accept the predetermined mismatch threshold, the voltage difference, and the input current from an input device.

13. A non-transitory computer-readable medium storing with instructions which, when executed by one or more data processors of at least one computing device, result in operations comprising:
collecting:
a predetermined mismatch threshold;
an input current associated with a master transistor of a current mirror circuit;
a number of current mirror circuits in a semiconductor chip;
a chip defect level of the semiconductor chip;
a channel width of the master transistor;
a gate length of the master transistor; and
first and second predetermined constants;
computing a mismatch value between an output current associated with a slave transistor of the current mirror circuit and the input current based on a voltage difference, the input current, the channel width, the gate length, and the first and second predetermined constants; and
comparing the mismatch value to the predetermined mismatch threshold and to generate a comparison result that specifies whether the mismatch value exceeds the predetermined mismatch threshold.

14. The non-transitory computer-readable medium of claim 13, further comprising receiving the predetermined mismatch threshold, the input current, the number of current mirror circuits, and the chip defect level from an input device.

15. The non-transitory computer-readable medium of claim 13, further comprising extracting the channel width and the gate length from a circuit design and to transmit the channel width and the gate length extracted thereby to the receiver.

16. The non-transitory computer-readable medium of claim 13, further comprising retrieving the first and second predetermined constants from a look-up table (LUT) and transmitting the first and second predetermined constants retrieved thereby to the receiver.

17. The non-transitory computer-readable medium of claim 16, further comprising the LUT.

18. The non-transitory computer-readable medium of claim 16, further comprising generating the LUT.

19. The non-transitory computer-readable medium of claim 16, further comprising accepting the predetermined mismatch threshold, the input current, the number of current mirror circuits, and the chip defect level from an input device.

20. The non-transitory computer-readable medium of claim 16, wherein the voltage difference is based on the chip defect level, the number of current mirror circuits, the channel width, the gate length, and a ratio of the output current to the input current.
